(19) United States
(12) Patent Application Publication
(10) Pub. No.: US 2021/0360816 A1
(43) Pub. Date: Nov. 18, 2021

(54) COMPUTER CABINET

(71) Applicant: EDAC ELECTRONICS TECHNOLOGY (HANGZHOU) CO., LTD, HANGZHOU (CN)

(72) Inventor: HUAN-TANG LIN, Taoyuan (CN)

(21) Appl. No.: 15/930,467

(22) Filed: May 13, 2020

(51) Int. Cl. H05K 7/14; G06F 1/20

(52) U.S. Cl. CPC H05K 7/1488; G06F 1/20

(57) ABSTRACT

A computer cabinet includes a radiating aluminium substrate; a case cover upturned above the radiating aluminium substrate to form a motherboard installation space between the radiating aluminium substrate and the case cover; and a motherboard installed in the motherboard installation space, and a CPU of the motherboard contacting closely with an upper surface of the radiating aluminium substrate. The radiating aluminium substrate in the disclosure is directly connected to the CPU of the motherboard, thus playing the role of active cooling, so that the computer can run in a noiseless state. Therefor there is no need to use a fan to dissipate heat, accordingly dust will not be inhaled through an air duct, thus enhancing host stability and extending service life.

### TECHNICAL FIELD OF THE INVENTION

The disclosure relates to the field of computer accessories, especially a computer cabinet.

### BACKGROUND OF THE INVENTION

The CPU of computer in the prior art dissipates heat through a fan, not only making noise but also inhaling a large amount of dust after a period of time, etc., thus affecting the stability and service life of the host.

### SUMMARY OF THE INVENTION

The disclosure provides a computer cabinet to solve the problem of noise in the computer cabinet in the prior art, and the problem that the stability and service life of the host will be affected because of the dust inhaled by the fan.

In order to solve the above problems, as an aspect of the disclosure, a computer cabinet is provided, which includes a radiating aluminium substrate; a case cover upturned above the radiating aluminium substrate to form a motherboard installation space between the radiating aluminium substrate and the case cover; and a motherboard installed in the motherboard installation space, and a CPU of the motherboard contacting closely with an upper surface of the radiating aluminium substrate.

Further, the case cover is provided with a concave part which is arranged correspondingly to the expansion card slot of the motherboard; the computer cabinet further includes a plurality of expansion slot covers removably connected with the case cover, the plurality of expansion slot covers installed at the position of the concave part.

Further, the computer cabinet further includes an adapter, the adapter includes a circuit board and an expansion slot installed on the circuit board, the circuit board inserts into the expansion card slot in the vertical direction, the expansion slot is installed on the circuit board in a horizontal direction.

Further, the computer cabinet further includes an expansion part, one end of the expansion part inserts into the expansion slot along the horizontal direction.

The radiating aluminium substrate in the disclosure is directly connected to the CPU of the motherboard, thus playing the role of active cooling, so that the computer can run in a noiseless state. Therefor there is no need to use a fan to dissipate heat, accordingly dust will not be inhaled through an air duct, thus enhancing host stability and extending service life. Furthermore, because the radiating aluminium substrate is a part of the cabinet housing, it takes full advantage of the external space to assist the computer cooling.

### BRIEF DESCRIPTION OF THE DRAWINGS

FIG. 1 is the explosion diagram of the disclosure.

FIG. 2 is the structural schematic of the expansion slot cover when it is partially installed;

FIG. 3 is the structural schematic of the expansion slot cover when it is fully installed;

FIG. 4 is the installation schematic of the expansion part.

Reference Numerals: 1, radiating aluminium substrate; 2, motherboard; 3, case cover; 4, concave part; 5, expansion card slot; 6, expansion slot cover; 7, adapter; 8, expansion slot; 9, expansion part.

### DETAILED DESCRIPTION OF THE EMBODIMENTS

The embodiments of the disclosure will be described below in detail in conjunction with the accompanying drawings, but the disclosure may be implemented in many different ways defined and covered by Claims.

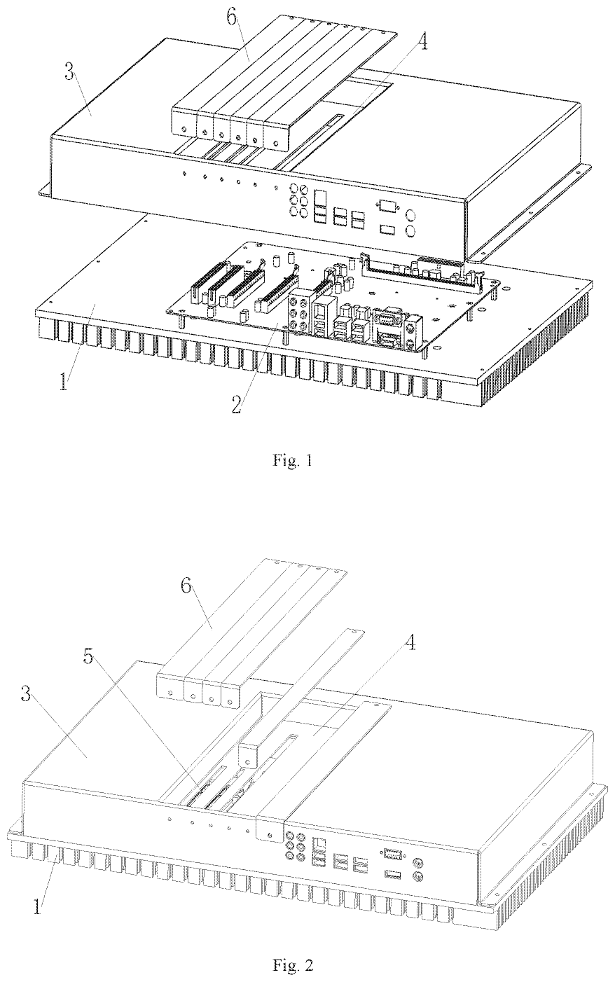

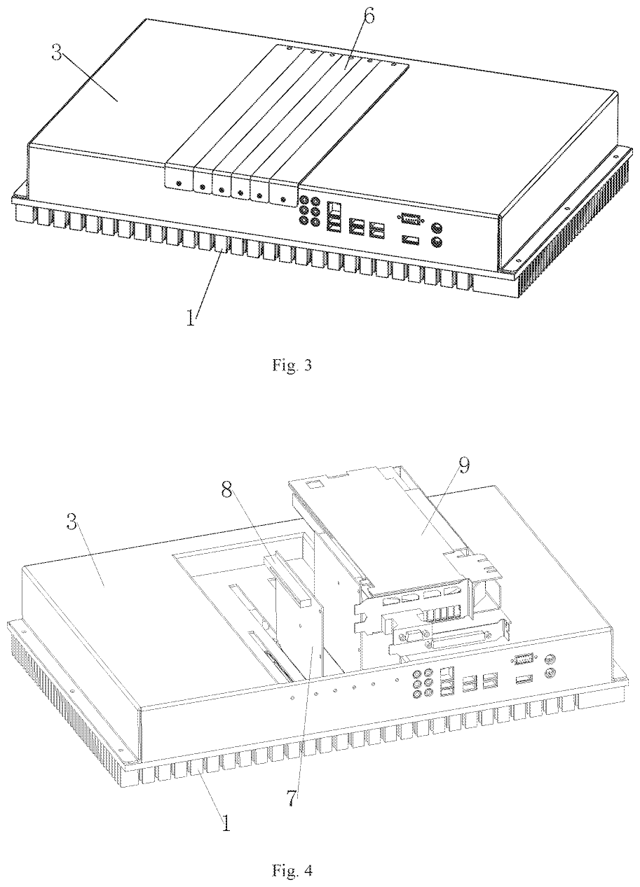

As shown in FIGS. 1 to 4, the disclosure provides a computer cabinet, which includes a radiating aluminium substrate 1, a case cover 3 upturned above the radiating aluminium substrate 1 to form a motherboard installation space between the radiating aluminium substrate 1 and the case cover 3, and a motherboard 2 installed in the motherboard installation space, and a CPU of the motherboard 2 contacts closely with an upper surface of the radiating aluminium substrate 1.

The radiating aluminium substrate 1 in the disclosure is directly connected to the CPU of the motherboard 2, thus playing the role of active cooling, so that the computer can run in a noiseless state. Therefor there is no need to use a fan to dissipate heat, accordingly dust will not be inhaled through an air duct, thus enhancing host stability and extending service life. Furthermore, because the radiating aluminium substrate 1 is a part of the cabinet housing, it takes full advantage of the external space to assist the computer cooling.

Preferably, the case cover 3 is provided with a concave part 4 which is arranged correspondingly to the expansion card slot 5 of the motherboard 2. The computer cabinet further includes a plurality of expansion slot covers 6 removably connected with the case cover 3, the plurality of expansion slot covers 6 installed at the position of the concave part 4. In this way, when it needs to insert the expansion card, the only operation is to open the corresponding expansion slot cover 6 with the characteristics of flexibility, simplicity, speediness, while it does not need to open the cabinet to carry out the corresponding operation when it needs to insert expansion parts as the current ordinary computer in the market very cumbersomely and time-consumingly.

Preferably, the computer cabinet further includes an adapter 7, the adapter 7 includes a circuit board and an expansion slot 8 installed on the circuit board, the circuit board inserts into the expansion card slot 5 in the vertical direction, the expansion slot 8 is installed on the circuit board in a horizontal direction. Preferably, the computer cabinet further includes an expansion part 9, one end of the expansion part 9 inserts into the expansion slot 8 along the horizontal direction. The adapter 7 with a 90-degree corner makes the expansion part 9 (such as a graphics card and other devices) inserted horizontally (siting flat) into the adapter 7 so as to connect with the motherboard. With this design, there is no significant change in the occupied space of the cabinet due to the insertion of the expansion part.

The above are only the preferred embodiment of the disclosure and are not intended to limit the disclosure, for those skilled in the art, various changes and variations may be made to the disclosure. Any modifications, equivalent replacements, improvements and the like within the spirit and principle of the disclosure shall be contained within the scope of protection of the claims of the disclosure.

What is claimed is:

1. A computer cabinet comprising
a radiating aluminium substrate (1);
a case cover (3) upturned above the radiating aluminium substrate (1) to form a motherboard installation space between the radiating aluminium substrate (1) and the case cover (3); and
a motherboard (2) installed in the motherboard installation space, and a CPU of the motherboard (2) contacting closely with an upper surface of the radiating aluminium substrate (1).

2. The computer cabinet according to claim 1, wherein the case cover (3) is provided with a concave part (4) which is arranged correspondingly to the expansion card slot (5) of the motherboard (2);
the computer cabinet further comprises a plurality of expansion slot covers (6) removably connected with the case cover (3), the plurality of expansion slot covers (6) installed at the position of the concave part (4).

3. The computer cabinet according to claim 2, wherein the computer cabinet further comprises an adapter (7), the adapter (7) comprises a circuit board and an expansion slot (8) installed on the circuit board, the circuit board inserts into the expansion card slot (5) in the vertical direction, the expansion slot (8) is installed on the circuit board in a horizontal direction.

4. The computer cabinet according to claim 3, wherein the computer cabinet further comprises an expansion part (9), one end of the expansion part (9) inserts into the expansion slot (8) along the horizontal direction.
